(19) United States
(12) Patent Application Publication
(10) Pub. No.: US 2026/0324163 A1
(43) Pub. Date: Oct. 15, 2026

(54) DISPLAY MODULE AND METHOD FOR MANUFACTURING THE SAME

(71) Applicant: Qisda Corporation, Taoyuan City (TW)

(72) Inventor: Po-Fu WU, Taoyuan City (TW)

(73) Assignee: Qisda Corporation, Taoyuan City (TW)

(21) Appl. No.: 19/466,679

(22) Filed: Feb. 2, 2026

(30) Foreign Application Priority Data
Feb. 17, 2025 (CN) 202510173771.9

(51) Int. Cl. H10H 29/85; H10H 29/01; H10H 29/24

(52) U.S. Cl. CPC H10H 29/8506; H10H 29/036; H10H 29/24

(57) ABSTRACT

A display module is provided. The display module includes a circuit board, a plurality of pixel structures, and a pocket. The pixel structures are arranged on the circuit board. Each of the pixel structures includes a plurality of light-emitting diode chips. The light-emitting diode chips are arranged on the circuit board. The pocket is arranged on the circuit board for separating the pixel structures from each other.

This application claims the benefit of People’s Republic of China application Serial No. 202510173771.9, filed Feb. 17, 2025, the subject matter of which is incorporated herein by reference.

### BACKGROUND OF THE INVENTION

### Field of the Invention

The invention relates in general to a display module and a method for manufacturing the same, and more particularly to a display module using light-emitting diode chips and a method for manufacturing the same.

### Description of the Related Art

In recent years, direct-view light-emitting diode (DVLED) display, which generates frames using light-emitting diodes, has been provided. In comparison to conventional liquid crystal display, DVLED display can provide images with larger dimensions, higher brightness and higher contrast. Generally speaking, DVLED display is composed of several small light boards. Each small light board may include hundred thousand to millions of light-emitting diode chips. To produce an aesthetic effect, the space between the light-emitting diode chips needs to be blackened with photoresist to form a light-blocking layer. When photoresist is erroneously coated on some light-emitting diode chips, undesired photoresist can be removed with plasma. However, if too many chips are covered with undesired photoresist, the light board can only be disposed of.

Light-emitting diode chips are very small. In most cases, its nominal height only reaches 80~85 micrometers (μm). Despite that the models and the manufacturers remain unchanged, standard dimensions of light-emitting diode chips of different colors still can be different due to the differences in the manufacturing process. Moreover, the chip’s specified nominal tolerance often reaches as high as±10μm to ±15μm, the tolerance of an actually obtained chip may even reach as high as ±20μm to ±30μm. That is, the difference between the heights of the light-emitting diode chips actually arranged on the small light boards can be considerably large. Under such circumstances, erroneous coating of photoresist is inevitable, making it difficult to increase product yield and decrease production cost.

### SUMMARY OF THE INVENTION

The present invention aims to prevent the above problems.

According to one embodiment of the present invention, a display module is provided. The display module includes a circuit board, a plurality of pixel structures, and a pocket. The pixel structures are arranged on the circuit board. Each of the pixel structures includes a plurality of light-emitting diode chips. The light-emitting diode chips are arranged on the circuit board. The pocket is arranged on the circuit board for separating the pixel structures from each other.

According to another embodiment of the present invention, a method for manufacturing display module is provided. The method includes the following steps. Firstly, a plurality of light-emitting diode chips of a plurality of pixel structures are provided on a circuit board. Next, a pocket is adhered to the circuit board. Then, the pocket is expanded, so that the pixel structures are separated from each other through the pocket.

In the display module of the invention, photoresist is replaced with pocket, hence avoiding erroneous coating of photoresist on the light-emitting diode chips, which would otherwise lead to further treatment or disposal of the light board. Thus, product yield can be increased, and production cost can be reduced.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 a top view of a display module according to an embodiment of the invention.

FIG. 2 is a cross-sectional view of a display module according to an embodiment of the invention.

FIG. 3 is a cross-sectional view of a display module according to another embodiment of the invention.

FIG. 4 is a cross-sectional view of a display module according to another embodiment of the invention.

FIG. 5 is a cross-sectional view of a display module according to another embodiment of the invention.

FIG. 6 is a cross-sectional view of a display module according to another embodiment of the invention.

FIGS. 7A-7F are schematic diagrams showing different stages of a manufacturing method of a display module according to an embodiment of the invention.

FIGS. 8A-8C are schematic diagrams showing different stages of a manufacturing method of a display module according to another embodiment of the invention.

### DETAILED DESCRIPTION OF THE INVENTION

Detailed descriptions of the invention are disclosed below with a number of embodiments. The disclosed embodiments and drawings are merely for explanatory and exemplary purposes only, not for creating limitations. For the accompanying drawings to be illustrated more clearly, elements of the accompanying drawings may not reflect actual scales. Besides, some elements and/or symbols may be omitted in some drawings. It can be expected that wherever conditions allow, elements and their characteristics disclosed in one embodiment can be incorporated in another embodiment without further explanation.

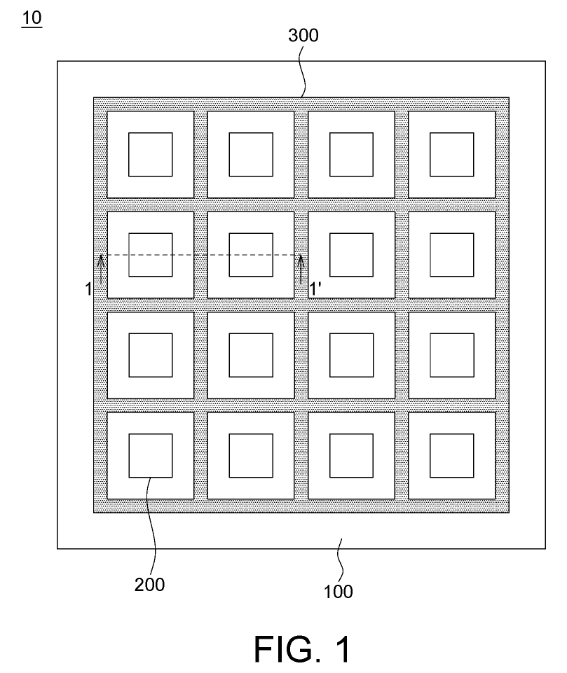

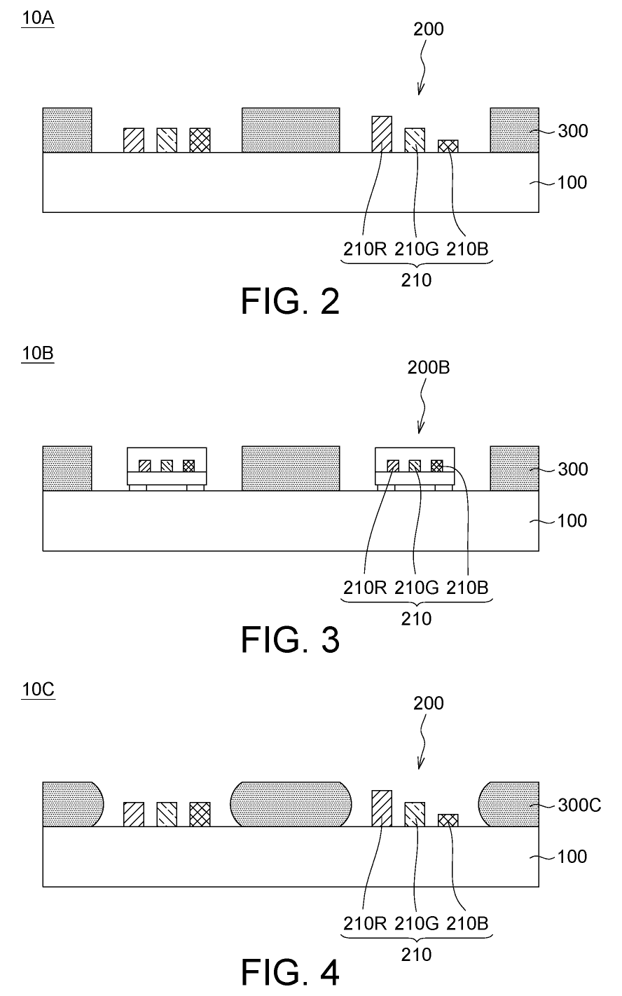

Referring to FIG. 1, a top view of a display module of the invention is shown. The display module 10 includes a circuit board 100, a plurality of pixel structures 200, and a pocket 300. The pixel structures 200 are arranged on the circuit board 100. Each of the pixel structures 200 includes a plurality of light-emitting diode chips 210 (illustrated in FIGS. 2-6). The light-emitting diode chips 210 are arranged on the circuit board 100. The pocket 300 is arranged on the circuit board 100 for separating the pixel structures 200 from each other.

The structure of the display module 10 may have different details. FIGS. 2-6 illustrate different cross-sectional views of a display module 10 according to different embodiments of the invention. For the convenience of differentiation, the display modules of FIGS. 2-6 according to different embodiments are respectively referred to as display modules 10A to 10E, and the cross-sectional lines respectively corresponding to the cross-sectional lines 1-1’ of the display module 10 of FIG. 1. Each of the details of the display module 10A to 10E described below can be applied to the display module 10. Under the circumstances where the features of other embodiments of the display module 10A to 10E are not affected, the details of the display module 10A to 10E can also be applied to other embodiments of the display module 10A to 10E. Descriptions of these details are not repeated here.

Referring to FIGS. 1 and 2, more details of the display module of the invention are provided. Specifically, the circuit board 100 can be realized by a printed circuit board. All circuits and/or other relevant electronic devices necessary for the light-emitting diode chips 210 can be arranged on the circuit board. However, it is to be understood that the invention is not limited thereto.

The light-emitting diode chips 210 of each of the pixel structures 200 may include the light-emitting diode chips 210 of different colors. For instance, the light-emitting diode chips 210 of each of the pixel structures 200 can be composed of a red light-emitting diode chip 210R, a green light-emitting diode chip 210G, and a blue light-emitting diode chip 210B. However, it is to be understood that the light-emitting diode chips 210 of each of the pixel structures 200 can be realized by different quantities and/or colors.

The dimensions of the light-emitting diode chips 210 are such as less than or equivalent to 250μm, that is, the length, width and height all are less than or equivalent to 250μm. At least two of the light-emitting diode chips 210 of at least one of the pixel structures 200 can have different heights. For instance, the light-emitting diode chips 210 of the pixel structures 200 at the left-hand side of FIG. 2 are illustrated as having an identical height, but the light-emitting diode chips 210 of the pixel structures 200 at the right-hand side of FIG. 2 are illustrated as having three different heights. At least two of the light- emitting diode chips 210 of at least one of the pixel structures 200 can have different horizontal dimensions, that is, different lengths and/or widths.

In an example, the dimensions of red light-emitting diode chips can be realized by 93(±15)μm*150(±15)μm*80(±10)μm, the dimensions of green and blue light-emitting diode chips can be realized by 89(±15)μm*150(±15)μm*80(±10)μm. In another example, the dimensions of all red, green, and blue light-emitting diode chips can be realized by 100(±15)μm*200(±15)μm*80(±10)μm. In another example, the dimensions of red light-emitting diode chip can be realized by 92(±25)μm*185(±25)μm*80(±10)μm, and the dimensions of green and blue light-emitting diode chip can be realized by 92(±25)μm*187(±25)μm*85(±15)μm. In another example, the dimensions of red light-emitting diode chip can be realized by 100(±25)μm*200(±25)μm*85(±10)μm, and the dimensions of green and blue light-emitting diode chip can be realized by 100(±38)μm*203(±38)μm*85(±15)μm. However, it is to be understood that the invention is not limited thereto.

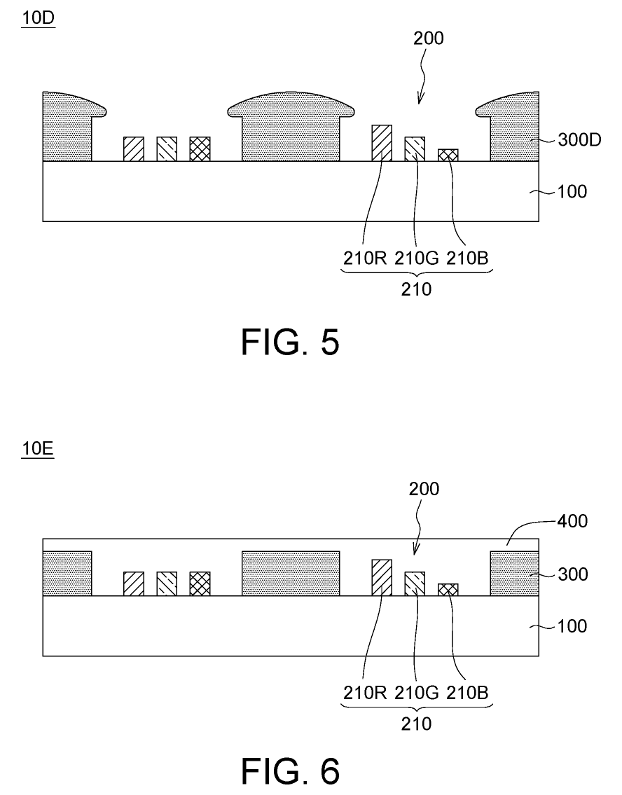

As indicated in FIG. 2, the light-emitting diode chips 210 of each of the pixel structures 200 can be provided individually, but the invention is not limited thereto. In the display module 10B according to another embodiment as indicated in FIG. 3, the light-emitting diode chips 210 of each of the pixel structures 200B are provided as a package.

Referring back to FIGS. 1 and 2, the pocket 300 can be filled with a suitable filler. In an example, the pocket 300 can be filled with air or a gas lighter than air, such as hydrogen or helium. Using gas instead of a solid colloid or a solid material as the filler advantageously reduces weight, particularly the use of a gas lighter than air can reduce more weight. In another example, the pocket 300 can be filled with a colloid, such as a curable colloid. Conventionally, curable colloid is a commonly used filler; curable colloid can support and fix the shape. In another example, the pocket 300 can be filled with a porous material, such as a foamed porous silicon. Porous material not only can support and fix the shape but also can reduce the weight to a certain degree. In another example, the filler can be formed of a combination of different materials.

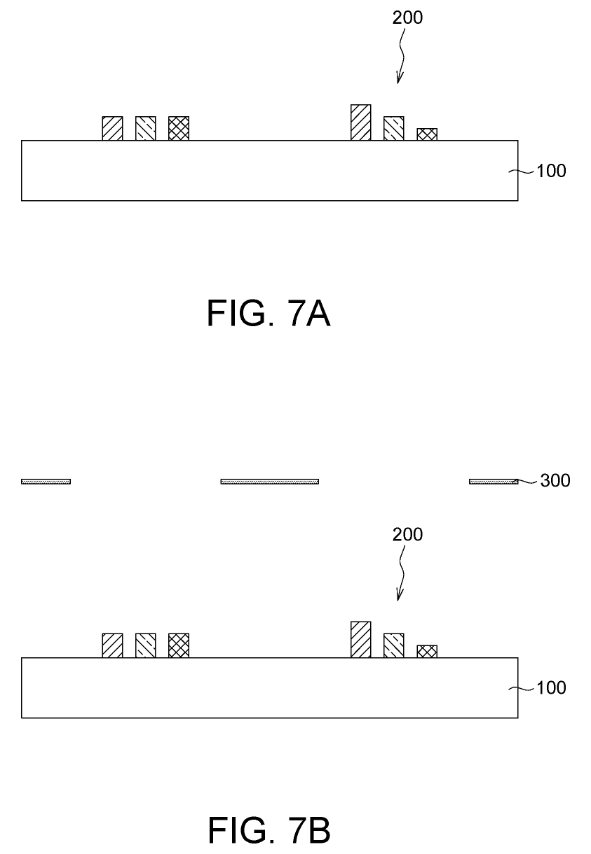

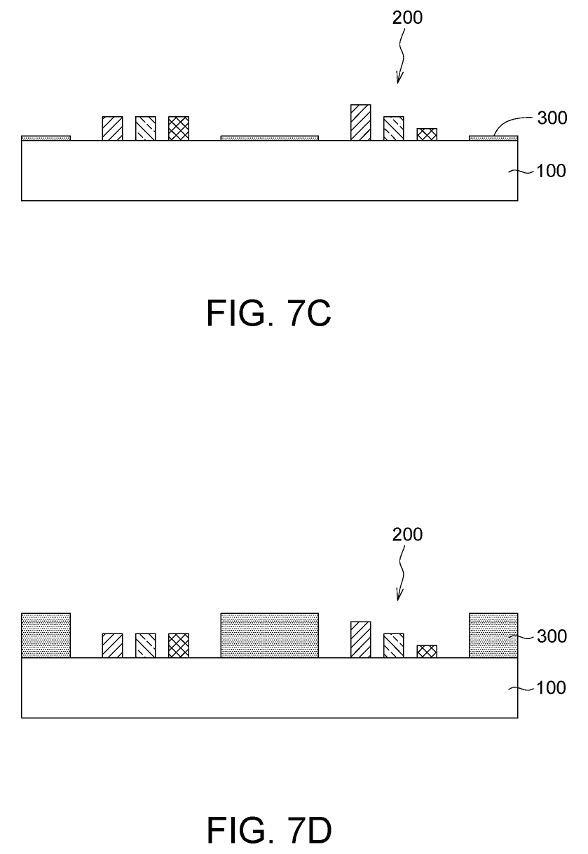

By controlling the filler type, filler amount, and filling process parameters (such as pressure), the shape and dimensions of the pocket 300 can be adjusted and optimized. As indicated in FIG. 1, the pocket 300 has a mesh-like cross section on a plane parallel to the top surface of the circuit board 100. Besides, the pocket 300 can have a cross section of various shapes on a plane perpendicular to the top surface of the circuit board 100; the shape of the cross section includes but is not limited to a rectangular shape, an arced shape, or a mushroom shape. As indicated in FIG. 2, the pocket 300 has a rectangular cross section on a plane (paper) perpendicular to the top surface of the circuit board 100. As indicated in FIG. 4, the pocket 300C of the display module 10C has an arc-shaped cross section on a plane (paper) perpendicular to the top surface of the circuit board 100. As indicated in FIG. 5, the pocket 300D of the display module 10D has a mushroom-shaped cross section on a plane (paper) perpendicular to the top surface of the circuit board 100.

As indicated in FIG. 2, the height of the pocket 300 can be equivalent to or greater than the height of the light-emitting diode chips 210. Under such circumstances, the pocket 300 can effectively avoid lateral light leakage, and can be preferably used as a light-blocking layer of the pixel structures 200. In another embodiment (not illustrated), the height of the pocket 300 can be less than the height of the light-emitting diode chips 210, so that the viewing angle can be increased. Since the display module 10A provides front lighting, lateral light leakage will not cause severe influence even when the height of the pocket 300 is less than the height of the light-emitting diode chips 210.

Apart from the shape and dimensions, the color and blackening degree of the pocket 300 also can be adjusted according to actual needs.

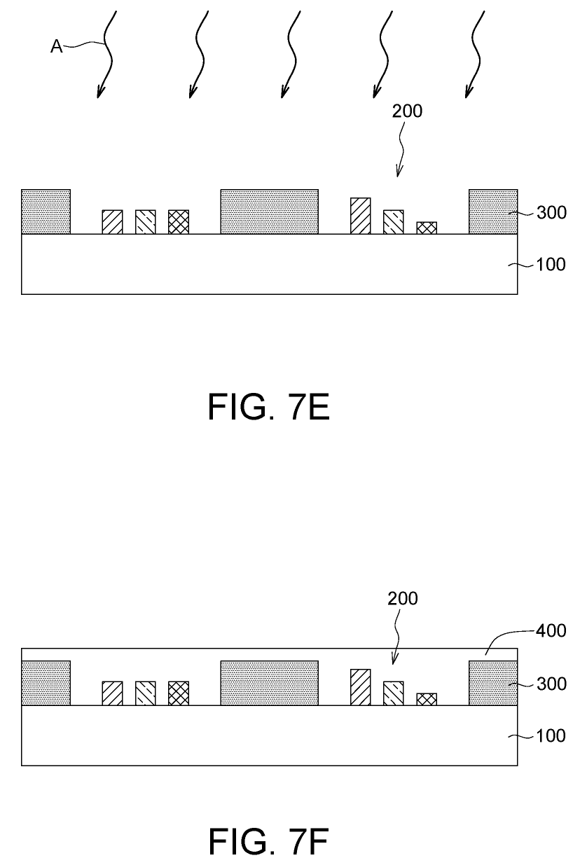

Referring to FIG. 6, selectively, the display module 10E may further include a surface protective adhesive 400, covering the pixel structures 200 and the pocket 300. The cured surface protective adhesive 400 can better assure that height product is consistent.

The method for manufacturing display module of the invention is disclosed below. The method includes the following steps. First, a plurality of light-emitting diode chips of a plurality of pixel structures are provided on a circuit board. Next, a pocket is adhered to the circuit board. Moreover, the pocket is expanded to separate the pixel structures from each other.

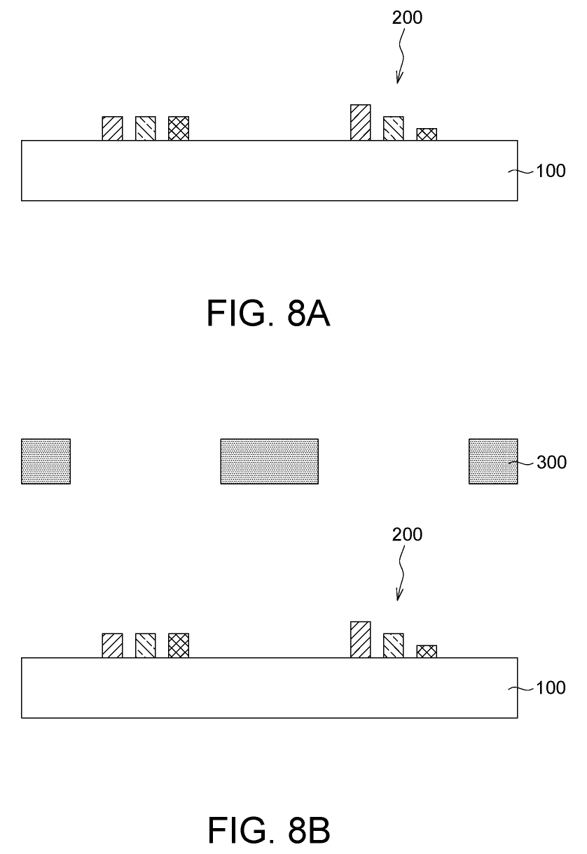

FIGS. 7A-7F are schematic diagrams showing different stages of a manufacturing method of a display module according to an embodiment of the invention.

First, as indicated in FIG. 7A, a plurality of light-emitting diode chips 210 of a plurality of pixel structures 200 (marked in FIGS. 2-6) are provided on a circuit board 100. The light-emitting diode chips 210 can be provided individually or as a package.

Next, as indicated in FIGS. 7B and 7C, a pocket 300 is adhered to the circuit board 100.

In the present embodiment, the step of expanding the pocket 300 is performed in the wake of the step of adhering the pocket 300 to the circuit board 100. As indicated FIG. 7D, the pocket 300 is expanded for separating pixel structures 200 from each other. The step of expanding the pocket 300 includes filling the pocket 300 with a filler. The filler may include at least one of air, a gas lighter than air, a curable colloid, and a porous material. By using a filling device, filler can be infused to the pocket 300 to make it expanded; by controlling process pressure and the amount of filler, it can be assured that the pocket 300 is expanded to specified dimensions. When the filler is realized by a curable colloid, the step of expanding the pocket 300 can further cure the colloid. Refer to the arrow A as indicated in FIG. 7E. The colloid can be cured using thermal curing or UV curing.

Selectively, as indicated in FIG. 7F, a surface protective adhesive 400 can be applied on the circuit board 100. The surface protective adhesive 400 covers the pixel structures 200 and the pocket 300.

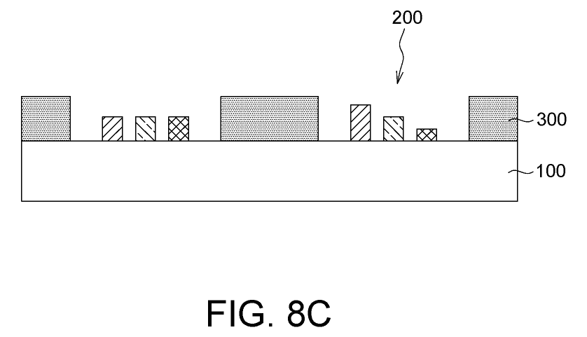

FIGS. 8A-8C are schematic diagrams showing different stages of a manufacturing method of a display module according to another embodiment of the invention.

Referring to FIG. 8A, a plurality of light-emitting diode chips 210 of a plurality of pixel structures 200 (marked in FIGS. 2-6) are provided on a circuit board 100.

Next, a pocket 300 is adhered to the circuit board 100. In the embodiment as indicated in FIG. 8B, the step of expanding the pocket 300 is performed prior to the step of adhering the pocket 300 to the circuit board 100. Then, the cured pocket 300 is adhered to the circuit board 100 as indicated in FIG. 8C.

To summarize, the invention provides a display module capable of reducing the influence caused by an erroneous coating of photoresist and a manufacturing method for the same. In a display module of the invention, as photoresist is replaced with the pocket, there is no need to remove undesired photoresist with plasma, not only greatly increasing product yield but also reducing cost. Besides, the shape and height of the pocket can be more easily controlled, and the weight can be reduced if the pocket is filled with a gas or a porous material. According to a display module of the invention, photoresist is not used, therefore the influence caused by the dimensions of the light-emitting diode chips is reduced, and there is no need to perform picking. Thus, both purchase cost and manufacturing cost can be reduced. Moreover, as dimension selection of the light-emitting diode chips becomes more flexible, customization flexibility is increased. Besides, since the light-emitting diode chips can be provided individually or as a package and the pitch of the pixel structures can be adjusted, customization flexibility is further increased.

While the invention has been described by way of example and in terms of the preferred embodiment (s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A display module, comprising:
a circuit board;
a plurality of pixel structures arranged on the circuit board, wherein each of the pixel structures comprises:
a plurality of light-emitting diode chips arranged on the circuit board; and
a pocket arranged on the circuit board for separating the pixel structures from each other.

2. The display module according to claim 1, wherein the dimensions of the light-emitting diode chips are less than or equivalent to 250 micrometers (μm).

3. The display module according to claim 1, wherein the light-emitting diode chips of each of the pixel structures is composed of a red light-emitting diode chip, a green light-emitting diode chip, and a blue light-emitting diode chip.

4. The display module according to claim 1, wherein at least two of the light-emitting diode chips of at least one of the pixel structures have different heights.

5. The display module according to claim 1, wherein at least two of the light-emitting diode chips of at least one of the pixel structures have different horizontal dimensions.

6. The display module according to claim 1, wherein the light-emitting diode chips of each of the pixel structures are provided individually or as a package.

7. The display module according to claim 1, wherein the pocket is filled with air or a gas lighter than air.

8. The display module according to claim 1, wherein the pocket is filled with a curable colloid.

9. The display module according to claim 1, wherein the pocket is filled with a porous material.

10. The display module according to claim 1, wherein the pocket has a mesh-like cross section on a plane parallel to the top surface of the circuit board.

11. The display module according to claim 1, wherein the pocket has a rectangular, arc-shaped, or mushroom-shaped cross section on a plane perpendicular to the top surface of the circuit board.

12. The display module according to claim 1, wherein the pocket is used as a light-blocking layer of the pixel structures.

13. The display module according to claim 1, further comprising:
a surface protective adhesive covering the pixel structures and the pocket.

14. A method for manufacturing a display module, comprising:
providing a plurality of light-emitting diode chips of a plurality of pixel structures on a circuit board;
adhering a pocket to the circuit board; and
expanding the pocket for separating the pixel structures from each other, through the pocket.

15. The method for manufacturing the display module according to claim 14, wherein the step of expanding the pocket is performed prior to the step of adhering the pocket to the circuit board.

16. The method for manufacturing the display module according to claim 14, wherein the step of expanding the pocket is performed in the wake of the step of adhering the pocket to the circuit board.

17. The method for manufacturing the display module according to claim 14, wherein the step of expanding the pocket comprises:
filling with the pocket a filler.

18. The method for manufacturing the display module according to claim 17, wherein the filler comprises at least one of air, a gas lighter than air, a curable colloid, and a porous material.

19. The method for manufacturing the display module according to claim 18, wherein the filler is a curable colloid, and the step of expanding the pocket further comprises curing the colloid.

20. The method for manufacturing the display module according to claim 14, further comprising:
applying a surface protective adhesive on the circuit board, wherein the surface protective adhesive covers the pixel structures and the pocket.
